(19) United States
(12) Patent Application Publication
(10) Pub. No.: US 2009/0097517 A1
(43) Pub. Date: Apr. 16, 2009

(54) VCSEL DEVICE AND METHOD FOR FABRICATING VCSEL DEVICE

(75) Inventors: Akira Sakamoto, Kanagawa (JP); Yasuaki Miyamoto, Tokyo (JP); Jun Sakurai, Kanagawa (JP)

Correspondence Address: FILDES & OUTLAND, P.C., 20916 MACK AVENUE, SUITE 2, GROSSE POINTE WOODS, MI, 48236, US

(73) Assignee: FUJI XEROX CO., LTD., Tokyo (JP)

(21) Appl. No.: 12/118,936

(22) Filed: May 12, 2008

(30) Foreign Application Priority Data
Oct. 10, 2007 (JP) 2007-264258

(51) Int. Cl. H01S 5/183; H01L 33/00

(52) U.S. Cl. 372/44.01; 438/46; 257/E33.005

(57) ABSTRACT

Provided is a VCSEL device that includes a substrate on which at least a first semiconductor multilayer film of a first conductivity type, an active region, and a second semiconductor multilayer film of a second conductivity type are stacked. The second semiconductor multilayer film forms a resonator together with the first semiconductor multilayer film. A conductive first protecting layer is formed in an area in the second semiconductor multilayer film. The area includes at least an emission outlet that emits laser light. An annular electrode is formed on the first protecting layer, and the emission outlet is formed in the annular electrode. An encapsulating material encapsulates at least the first protecting layer and the annular electrode.

### CROSS-REFERENCE TO RELATED APPLICATION

This application is based on and claims priority under 35 USC 119 from Japanese Patent Application No. 2007-264258 filed Oct. 10, 2007.

### BACKGROUND

1. Technical Field

This invention relates to a Vertical-Cavity Surface-Emitting Laser diode (hereinafter referred to as VCSEL) device that is applicable to a light source for optical data processing or high-speed optical transmission, and to a method for fabricating the VCSEL device.

2. Related Art

Recently, in technical fields such as optical communication or optical storage, there has been a growing interest in VCSELs. VCSELs have excellent characteristics which edge-emitting semiconductor lasers do not have. For example, VCSELs have the lower threshold current and the smaller power consumption than those edge-emitting semiconductor lasers have. With VCSELs, a round-shaped light spot can be easily obtained, and evaluation can be performed while they are on a wafer, and light sources can be arranged in two-dimensional arrays. With these characteristics, demands for VCSELs as light sources have been expected to grow especially in the communication field.

A VCSEL may be packaged into a ceramic material, a can, or a resin encapsulation, for example. Among them, the resin encapsulation is less expensive and has often been applied to practical use. However, if a resin encapsulated VCSEL is driven in high humidity at a high temperature (for example, 85% and 85 degrees centigrade), the life of the VCSEL tends to be shorter than that in a lower humidity at ambient temperature. This is because the stress caused when the resin thermally expands or thermally contract may be applied onto a surface of a protecting layer of the VCSEL, and thus moisture may seep in from the protecting layer that is deformed by the stress. The moisture may damage the portion of the surface of the VCSEL that includes an emission outlet, and light output property may be degraded. On a surface of the VCSEL, plural materials such as an electrode or a protecting layer that covers the electrode may be formed, and each of the materials may have a different coefficient of thermal expansion. In addition, each of the plural materials and the resin may have a different degree of adhesiveness, and thus especially the protecting layer that protects the emission outlet tends to be delaminated.

The present invention aims to address the issues of the related arts described above, and to provide a VCSEL device in which water or moisture from outside may be prevented from seeping in, and the life of the VCSEL device may be improved.

### SUMMARY

An aspect of the present invention provides a VCSEL device that includes a substrate on which at least a first semiconductor multilayer film of a first conductivity type, an active region, and a second semiconductor multilayer film of a second conductivity type are stacked. The second semiconductor multilayer film forms a resonator together with the first semiconductor multilayer film. A conductive first protecting layer is formed in an area in the second semiconductor multilayer film. The area includes at least an emission outlet that emits laser light. An annular electrode is formed on the first protecting layer, and the emission outlet is formed in the annular electrode. An encapsulating material encapsulates at least the first protecting layer and the annular electrode.

### BRIEF DESCRIPTION OF THE DRAWINGS

Exemplary embodiments of the present invention will be described in detail based on the following figures, wherein:

FIG. 1 is a schematic cross sectional view of a semiconductor light-emitting device that is resin encapsulated;

FIG. 2 is a plan view of a VCSEL according to a first example of the present invention;

FIG. 3 is a cross sectional view of the VCSEL shown in FIG. 2 taken along line A-A;

FIG. 4 illustrates a VCSEL of the first example, in which an emission protecting layer is delaminated;

FIG. 5 is a cross-sectional view of a VCSEL according to a second example of the present invention;

FIG. 6 is a cross-sectional view of a VCSEL according to a third example of the present invention;

FIGS. 7A to 7C are cross sectional views illustrating a method for fabricating a VCSEL according to the first example of the present invention;

FIGS. 8A and 8B are cross sectional views illustrating a method for fabricating a VCSEL according to the first example of the present invention;

FIGS. 9A and 9B are cross sectional views illustrating a method for fabricating a VCSEL according to the first example of the present invention;

FIGS. 10A and 10B are schematic cross sectional views of a configuration of a module according to an example, in which a VCSEL is used;

FIG. 11 illustrates an example of a configuration of a light source device in which a VCSEL is used;

FIG. 12 illustrates a schematic cross sectional view of a configuration of a light source in which the module shown in FIG. 10A is used;

FIG. 13 illustrates a configuration of the module shown in FIG. 10A that is used in a spatial transmission system;

FIG. 14A is a block diagram illustrating a configuration of an optical transmission system;

FIG. 14B illustrates an outer configuration of an optical transmission device; and

FIG. 15 illustrates a video transmission system in which the optical transmission device of FIG. 14B is used.

### DETAILED DESCRIPTION

Referring to the accompanying drawings, exemplary embodiments for implementing the present invention will be described. As an example, a GaAs system VCSEL is used.

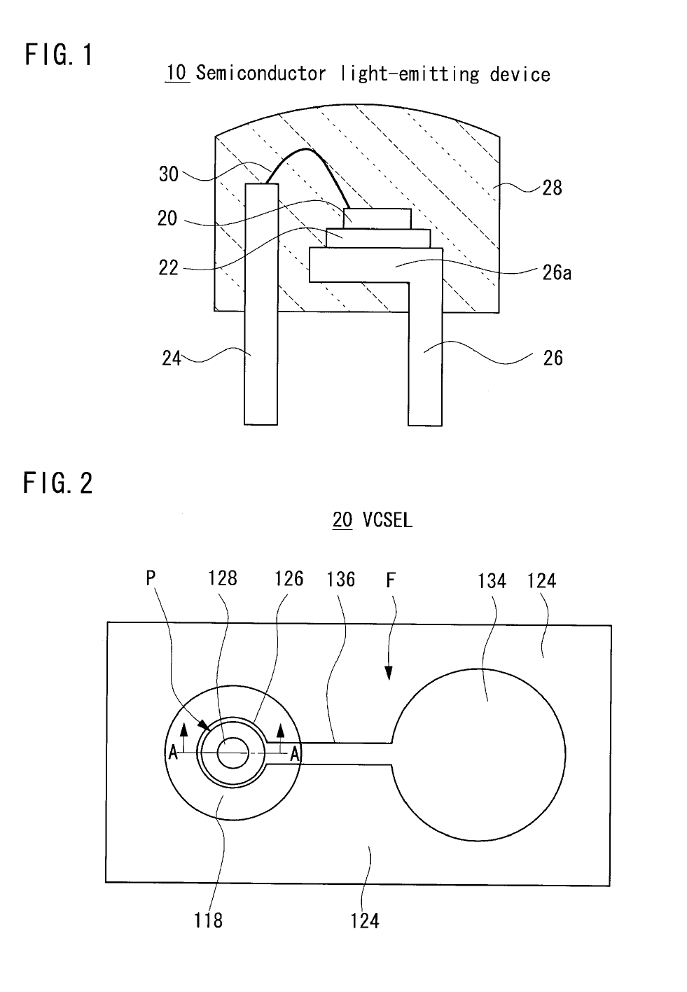

FIG. 1 is a schematic cross sectional view of a semiconductor light-emitting device that includes a resin encapsulated VCSEL. A semiconductor light-emitting device 10 may include a VCSEL 20 that emits laser light, a submount 22 on which the VCSEL 20 is fixed, plural lead terminals 24 and 26 electrically connected to the VCSEL 20, and a resin 28 made of an optical transparent material and encapsulates the VCSEL 20 and other components.

The submount 22 is made of a conductive material. On an upper surface of the submount 22, the VCSEL 20 is fixed with a conductive adhesive or the like. The back surface of the submount 22 is fixed to a die pad 26a with a conductive adhesive or the like. The die pad 26a may be formed by bending an upper end of the lead terminal 26 at approximately right angle.

A p-side electrode on an upper surface of the VCSEL 20 is electrically connected to the lead terminal 24 by a bonding wire 30. An n-side electrode on the back surface the VCSEL 20 is electrically connected to the lead terminal 26 via the submount 22. The lead terminal 24 is an anode of the VCSEL 20, and the lead terminal 26 is a cathode of the VCSEL 20. The VCSEL 20, the submount 22, upper portions of the lead terminals 24 and 26, the die pad 26a are encapsulated by the resin 28.

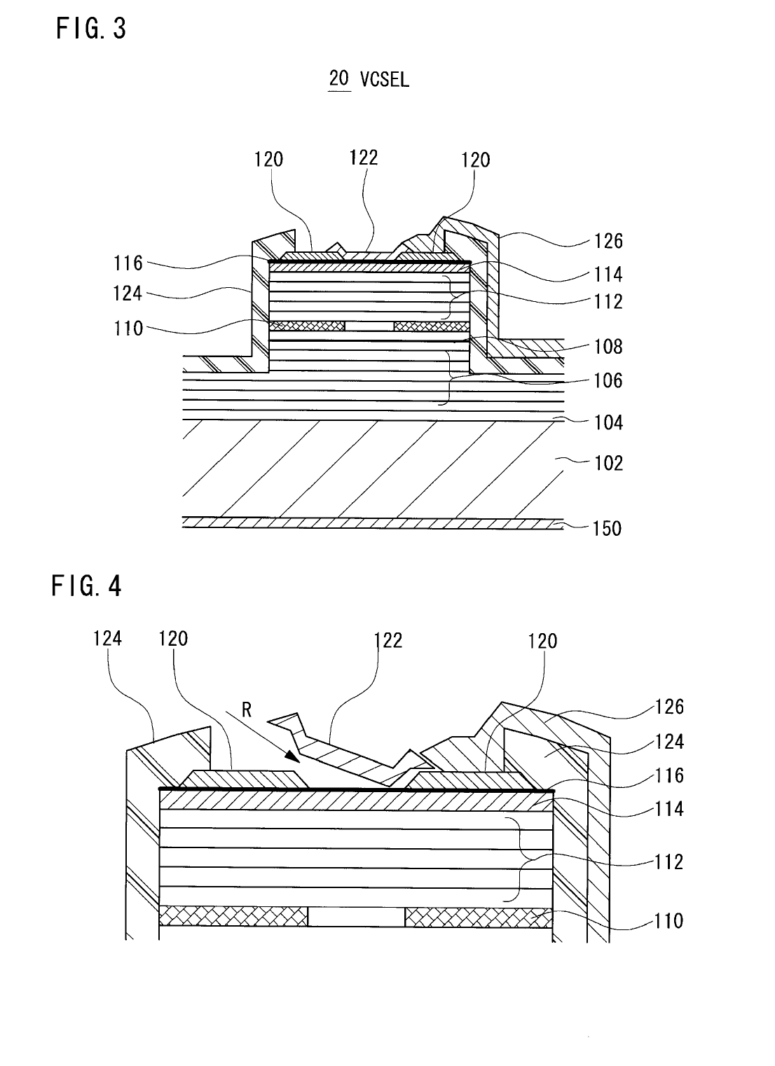

FIG. 2 is a plan view of a VCSEL according to a first example. FIG. 3 is a cross sectional view of FIG. 2 taken along line A-A. As shown in FIG. 2, a ring shaped groove 118 is formed in the VCSEL 20. By the groove 118, a cylindrical post P that becomes a portion that emits laser light, and a pad formation region F that is isolated from the post P are formed. The pad formation region F includes same semiconductor layers as the post P does. Whole surface of the pad formation region F is covered with an interlayer insulating film 124. A pad electrode 134 is connected to a p-side upper electrode 126 formed in the post P through a wiring electrode 136 that extends through the groove 118. The bonding wire 30 is connected to the pad electrode 134.

FIG. 3 is a cross sectional view of a VCSEL that includes the post P. The VCSEL 20 includes an n-side lower electrode 150 on the back surface of an n-type GaAs substrate 102. The VCSEL 20 further includes semiconductor layers stacked on the substrate 102: an n-type GaAs buffer layer 104; a lower Distributed Bragg Reflector (DBR) 106 made of n-type AlGaAs semiconductor multilayer; an active region 108; a current confining layer 110 made of p-type AlAs; an upper DBR 112 made of p-type AlGaAs semiconductor multilayer; and a p-type GaAs contact layer 114.

The lower DBR 106 and the upper DBR 112 form a resonator structure, and the active region 108 and the current confining layer 110 are interposed therebetween. The current confining layer 110 includes an oxidized region formed by selectively oxidizing AlAs that is exposed on the side surface of the post P, and a conductive region surrounded by the oxidized region, and performs current and light confining in the conductive region.

In this example, a surface protecting layer 116 is formed on whole surface of the contact layer 114 to prevent water or moisture or the like from outside from seeping in. The surface protecting layer 116 may be made of, for example, a conductive metal thin film. The thickness of the metal thin film may be selected such that laser light to be emitted can pass through it. For example, when laser light has the wavelength of 850 nm, the thickness of the metal thin film may be about 10 nm. For the surface protecting layer 116, a highly water-resistant and corrosion resistant conductive material, such as Au or Cr, may be suitable. The surface protecting layer 116 may be either of a single layer or multiple layers.

On an upper surface of the surface protecting layer 116, a ring shaped annular electrode 120 made of a conductive material, such as a metal or the like, is formed. The annular electrode 120 is electrically connected to the contact layer 114 through the surface protecting layer 116. In a center portion of the annular electrode 120, an opening that defines a region that emits laser light, i.e., an emission outlet, is formed. The surface protecting layer 116 exposed by the annular electrode 120 is further covered with a round-shaped emission protecting layer 122. A material and film thickness adequate for the emission protecting layer 122 may be selected such that laser light passes through the layer 122, in consideration of relation with the surface protecting layer 116.

The interlayer insulating film 124 is formed such that it covers the side surface of the post P and a top portion of the post P. In other words, the interlayer insulating film 124 covers outer periphery of the annular electrode 120, and the surfaces of the groove 118 and the pad formation region F. At a top portion of the post P, a round-shaped contact hole is formed in the interlayer insulating film 124, such that a portion of the annular electrode 120 and the emission protecting layer 122 are exposed. The p-side upper electrode 126 is connected to the annular electrode 120 through the contact hole. The upper electrode 126 is connected to the pad electrode 134 in the pad formation region F through the wiring electrode 136 that extends through the groove 118, from one side of the post P as shown in FIG. 2. As shown in FIG. 1, the surface of the VCSEL is, in other words, the annular electrode 120, the emission protecting layer 122, the interlayer insulating film 124, and the upper electrode 126 are, encapsulated by an optical transparent resin 28.

By forming the surface protecting layer as shown in FIG. 3, water or moisture seeping into the contact layer 114 can be effectively prevented. FIG. 4 illustrates a configuration in which the emission protecting layer is delaminated. For example, when a VCSEL is driven in high humidity at a high temperature, the resin 28 that encapsulates the VCSEL 20 may thermally expand or thermally contract due to external temperatures or heat generation by the VCSEL itself. The difference in the coefficients of thermal expansion between the resin 28 and the materials that make up the VCSEL may cause stress on the VCSEL. The post P is a cylindrical shaped structure, and thus would easily be subject to the stress. Especially when the stress is applied to a top portion of the post P, the emission protecting layer 122 may be easily delaminated as shown in FIG. 4. The delamination is related to the difference in the coefficients of thermal expansion between the resin and the materials, and also the difference in degrees of adhesiveness to resin 28. In other words, the emission protecting layer 122 may be made of an insulating film such as SiON, SiO2, or the like, while the annular electrode 120 and the p-side upper electrode 126 may be made of Au or the like. The former has a higher degree of adhesiveness to the resin 28, and tends to easily be affected by the thermal contraction of the resin 28. The moisture contained in the resin 28, or the moisture seeped from a crack caused in the resin 28 may seep in from the portion the emission protecting layer 122 is delaminated, as shown by an arrow R. In this example, the whole surface of the contact layer 114 is covered with the surface protecting layer 116, and thus the seeped moisture does not directly contact the contact layer 114, and thus corrosion or deformation of the contact layer 114 can be prevented. By this configuration, electric properties of the contact layer 114 and degradation of the emission outlet on the surface of the contact layer 114 can be prevented.

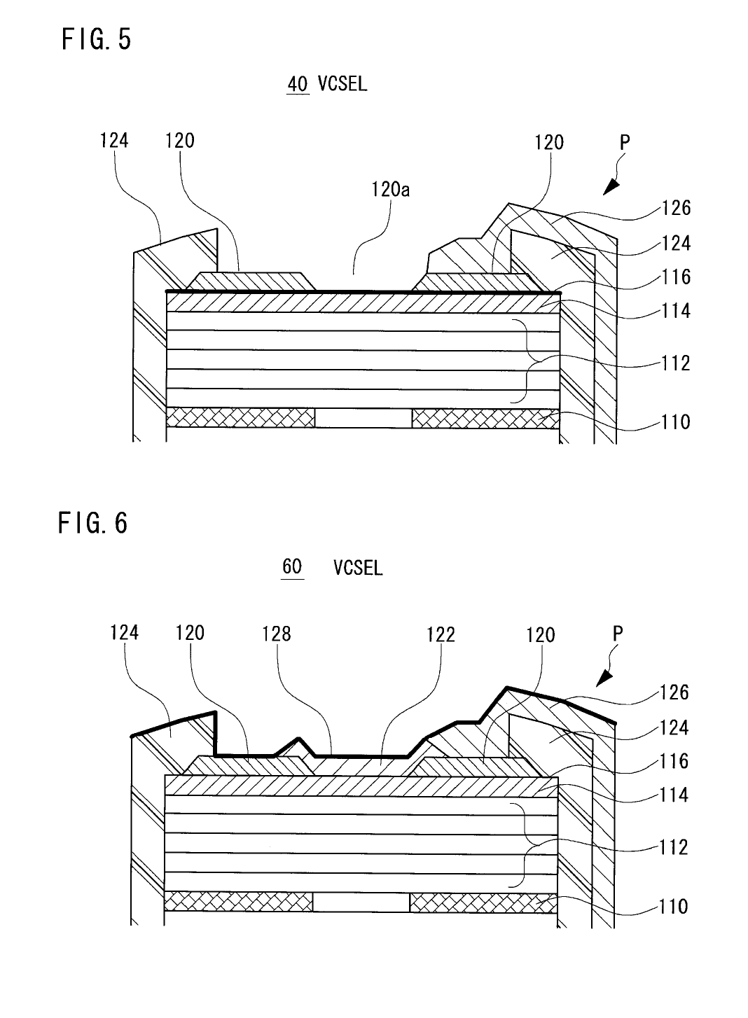

FIG. 5 is a cross-sectional view of a VCSEL according to a second example of the present invention. The arrangement of a VCSEL 40 of the second example is same as in the first example, excepting that the emission protecting layer 122 is removed. In the second example, the surface protecting layer 116 prevents moisture from seeping into the contact layer 114, and also acts as an emission protecting layer that protects an emission outlet. Because the emission protecting layer 122 is removed, the annular electrode 120 and the surface protecting layer 116 contact the resin 28 in the area near an emission outlet 120a. When both of the annular electrode 120 and the surface protecting layer 116 are made of metals, the interface with the resin 28 in the area near the emission outlet 120a is made up of the metals only, and thus their degrees of adhesiveness to the resin 28 become approximately a same level. This may prevent the stress from concentrating toward the area near the emission outlet. At least the surface protecting layer 116 and the annular electrode 120 are encapsulated by the resin 28. Even if moisture seeps from a crack or the like in the resin 28, the contact layer 114 is protected by the surface protecting layer 116.

FIG. 6 is a cross-sectional view of a VCSEL according to a third example of the present invention. In a VCSEL 60 according to the third example, the surfaces of the post P that becomes an interface with the resin 28 is, in other words, the surface of the interlayer insulating film 124, the annular electrode 120, the emission protecting layer 122, and the upper electrode 126 are, covered with an interface protecting layer 128. Preferably, the interface protecting layer 128 is made of a material, such as Au or Cr, which has a low degree of adhesiveness to the resin 28 and is transparent and less corrosive. For example, the interface protecting layer 128 has a thickness of about 10 nm. Such interface protecting layer 128 may prevent the top portion of the post P from being subject to the stress when the resin 28 thermally contracts in high humidity at a high temperature, and prevent the emission protecting layer 122 from delaminating, and prevent moisture from seeping into the contact layer 114.

The interface protecting layer 128 is not necessarily made of a conductive material, but may be made of an insulating material. Again in this case, it is preferable that the material of the layer 128 has an optical transparency, and a low degree of adhesiveness to the resin 28. The VCSEL 60 according to the third example may include the surface protecting layer 116 that covers whole surface of the contact layer 114, as same in the first example. In that case, moisture seeping into the contact layer 114 can be more effectively prevented.

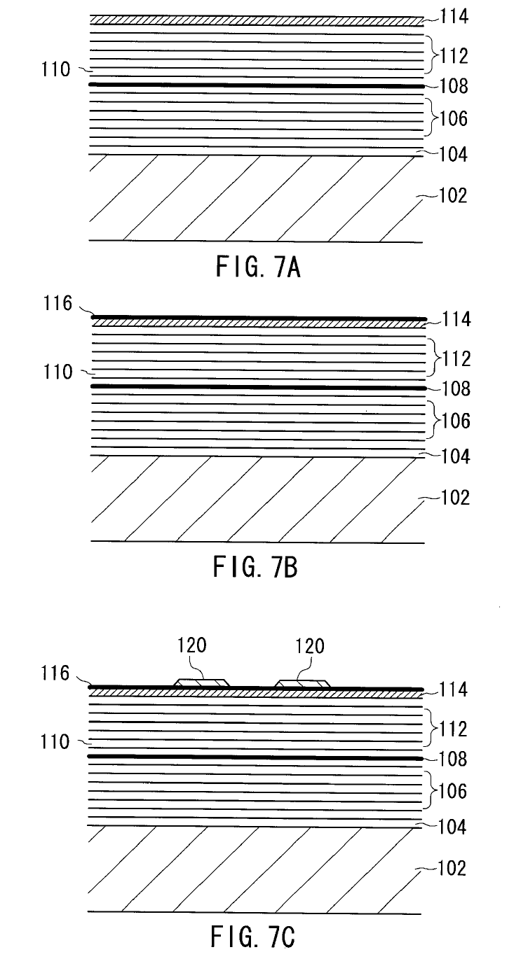

Referring now to FIGS. 7A to 9G, a method for fabricating a VCSEL according to an example will be described. As shown in FIG. 7A, by Metal Organic Chemical Vapor Deposition (MOCVD), an n-type GaAs buffer layer 104 having a carrier concentration of 1×10¹⁸ cm⁻³ and a thickness of about 0.2 micrometers is formed on an n-type GaAs substrate 102. Sequentially stacked on the buffer layer 104 are: a lower n-type DBR 106 having a carrier concentration of 1×10¹⁸ cm⁻³ and a total thickness of about 4 micrometers in which 40.5 periods of Al_{0.9}Ga_{0.1}As and Al_{0.3}Ga_{0.7}As, each having a thickness of ¼ of the wavelength in the medium, are alternately stacked; an active region 108 having a thickness of the wavelength in the medium and made of an undoped lower Al_{0.5}Ga_{0.5}As spacer layer, an undoped quantum well active layer (thickness of 90 nm, made of three Al_{0.11}Ga_{0.9}As quantum well layers, thickness of 50 nm, four Al_{0.3}Ga_{0.7}As barrier layers), and an undoped upper Al_{0.5}Ga_{0.5}As spacer layer; a p-type AlAs layer 110, an upper p-type DBR 112 having a carrier concentration of 1×10¹⁸ cm⁻³ and a total thickness of about 2 micrometers in which 30 periods of an Al_{0.9}Ga_{0.1}As and an Al_{0.3}Ga_{0.7}As, each having a thickness of ¼ of the wavelength in the medium, are alternately stacked; and a p-type GaAs contact layer 114 having a carrier concentration of 1×10¹⁹ cm⁻³ and a thickness of about 10 nm.

Deposition to form these layers may be continuously performed by using trimethyl gallium, trimethyl aluminum, or arsine as a source gas, which are changed sequentially, and using cyclopentadinium magnesium as a p-type dopant material, and silane as an n-type dopant material, with the substrate temperature being kept at 750 degrees centigrade, without breaking vacuum. Although not disclosed herein in detail, in order to reduce electrical resistance of the DBR, it is also possible to provide an area having a thickness of about 9 nm, in which Al-composition ratio is changed stepwise from 90% to 30%, in the interface between the Al_{0.9}Ga_{0.1}As and the Al_{0.3}Ga_{0.7}As.

By using an EB deposition apparatus, a conductive metal thin film, preferably having a thickness that does not interfere emission of laser light, for example, about 10 nm, is deposited on the surface of the contact layer 114. For the metal thin film, a highly water-resistant and less corrosive metal, such as Au or Cr, may be selected. With this metal film, a surface protecting layer 116 is formed on the surface of the contact layer 114 as shown in FIG. 7B.

Then, a resist pattern is formed on the crystal growth layer by a photolithography process. As a material for a p-side electrode, a metal film made of Au or titanium is deposited on the whole substrate that includes the resist. Then, the resist pattern is removed by lift-off, and an annular electrode 120 is formed on the upper surface of the surface protecting layer 116, as shown in FIG. 7C. For the annular electrode 120 that becomes a p-side electrode, Ti/Au or Ti/Pt/Au can be used, for example. The annular electrode 120 is formed at a position that is an approximate center portion of the post P. An opening at a center portion of the annular electrode 120 becomes an emission area that emits laser light. The diameter of the opening in the annular electrode 120, which becomes the emission area, is preferably about 3 to 20 micrometers.

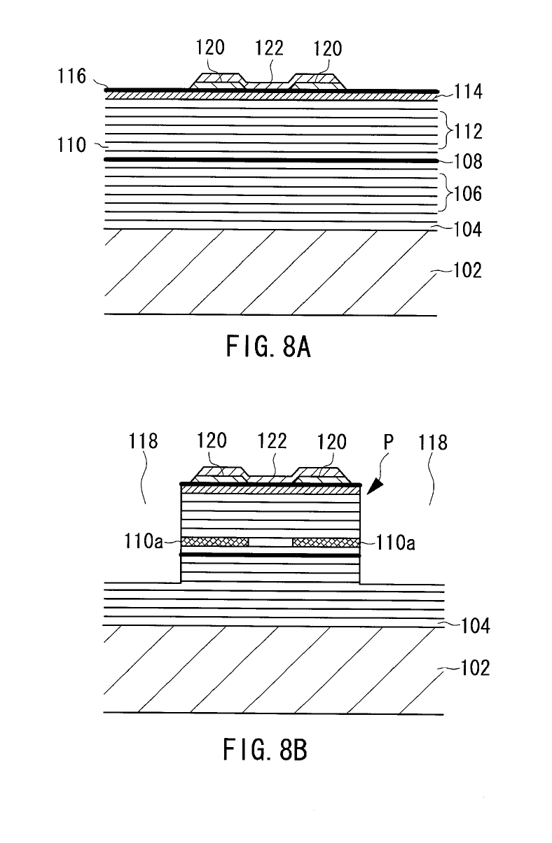

Then, an SiON film is deposited, for example, by plasma CVD or sputtering. The SiON film is etched out, excepting the SiON film formed on the surface of the annular electrode 120 and the opening. By this etching, as shown in FIG. 8A, at a potion that becomes the post P, an emission protecting layer 122 is formed that covers the annular electrode 120 and the opening. With this configuration, the annular electrode 120 and the emission area are protected by the emission protecting layer 122 during a post forming process and an oxidation process that are described below.

By a photolithography process, a resist mask is formed on the crystal growth layer that includes the annular electrode 120 and the emission protecting layer 122. Then, a reactive ion etching is performed by using chlorine or chlorine and boron trichloride as an etching gas to form an annular groove 118 to a middle portion of the lower DBR 106. By this etching, a cylindrical or rectangular prism-shaped semiconductor pillar (post) P having a diameter of about 10 to 30 micrometers may be formed.

As shown in FIG. 8B, after removing the resist mask, the substrate is exposed to a vapor atmosphere at 340 degrees centigrade, for example, for a certain amount of time to perform an oxidation process. The AlAs layer that forms the current confining layer 110 has a significantly faster oxidation speed than the Al_{0.9}Ga_{0.1}As layer or the Al_{0.3}Ga_{0.7}As layer that also form a portion thereof. Therefore, from the side surface of the post P, an oxidized region 110a that reflects the outline of the post is formed. A non-oxidized region that is not oxidized becomes a current injection region or a conductive region.

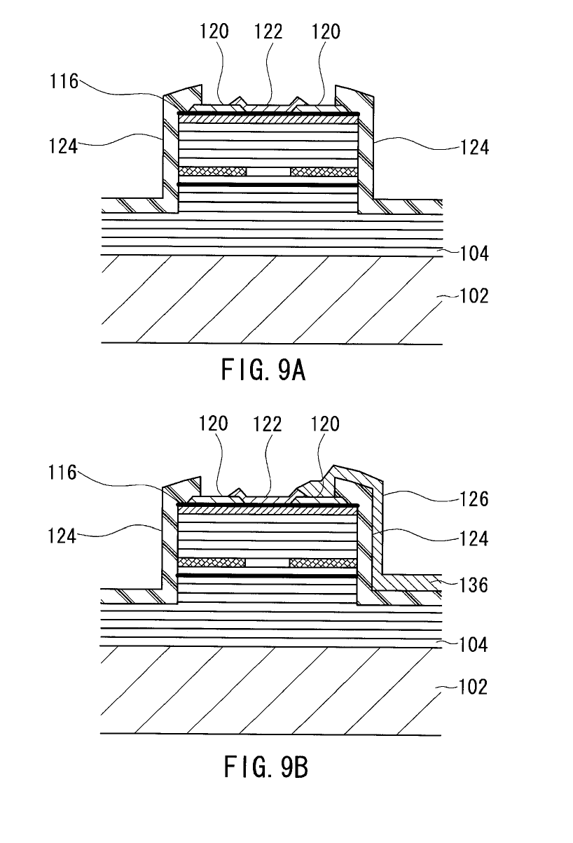

By using plasma CVD or the like, SiN that becomes an interlayer insulating film 124 is then deposited on the whole surface of the substrate that includes a groove 118 and a pad formation region F (not shown). After that, by using a general photolithography process and sulfur hexaflouride as an etching gas, a portion of the interlayer insulating film 124 and a portion of the emission protecting layer 122 are etched out, and a round-shaped contact hole is formed in the interlayer insulating film 124 at a top portion of the post P, as shown in FIG. 9A. By this etching, a portion of the annular electrode 120 and the emission protecting layer 122 are exposed.

By using a photolithography process, a resist pattern is formed. From above thereof, as a material for a p-side electrode, Au or Ti having a thickness in a range of 100 to 1000 nm, preferably 600 nm, is deposited on the whole surface of the substrate by using an EB deposition apparatus. Then, the resist pattern is removed together with the Au or Ti on the resist pattern to form an upper electrode 126 as shown in FIG. 9B. At this time, a pad electrode 134 and a wiring electrode 136 are concurrently formed on the interlayer insulating film 124. The p-side electrode material to be deposited may be preferably two or more layers, in order to reduce the number of pinhole.

On the back surface of the substrate 102, Au/Ge is deposited as an n-side electrode. After that, annealing is performed at an annealing temperature in a range of 250 to 500 degrees centigrade, and preferably at 300 to 400 degrees centigrade, for 10 minutes. The annealing duration is not necessarily limited to 10 minutes, and may be in a range from 0 to 30 minutes. The method for deposition is not necessarily limited to the EB deposition, and a resistance heating method, sputtering method, magnetron sputtering method, or CVD method may be used. The method for annealing is not necessarily limited to the thermal annealing that uses a general electric furnace. A similar effect can be obtained by flash annealing or laser annealing using infrared radiation, annealing by high frequency heating, annealing by electron beam, or annealing by lamp heating. The fabrication method described above is an example, and not necessarily limited to the method.

The VCSEL fabricated as described above may be fixed onto a submount and encapsulated by the resin 28, as shown in FIG. 1.

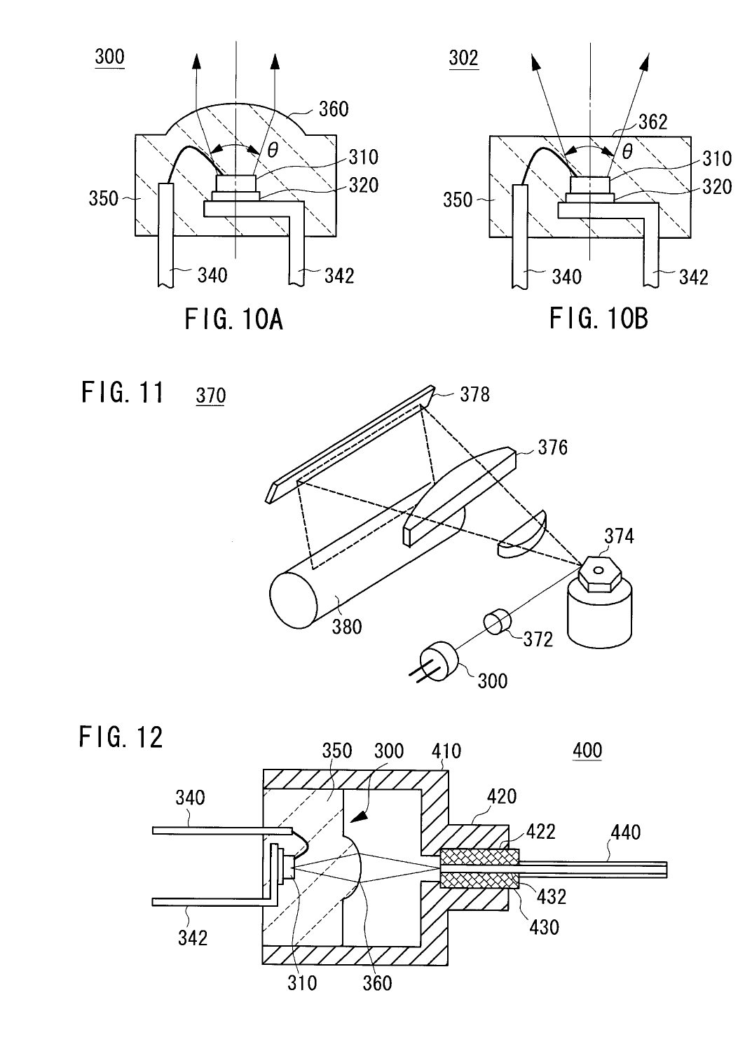

Referring to the accompanying drawings, a module, a light source, a spatial transmission system, an optical transmission device, or the like will be now described. The semiconductor light-emitting device 10 shown in FIG. 1 may be used as a module by modifying the emission surface of the resin 28. FIG. 10A is a cross sectional view illustrating a configuration in which a semiconductor light-emitting device is used as a module. In a module 300, a VCSEL 310, a submount 320, and a portion of lead terminals 340 and 342 are encapsulated by a resin 350. The lead 340 is electrically coupled to an anode of the VCSEL 310, and the other lead 342 is electrically coupled to a cathode of the VCSEL 310.

The upper surface of the resin 350 may be formed into, for example, a spherical or an aspherical shaped convex portion 360. The optical axis of the convex portion 360 is positioned such that it approximately matches with the center of the emission outlet of the VCSEL 310. The distance between the VCSEL 310 and the convex portion 360 may be adjusted such that the ball lens 360 is contained within the divergence angle θ of the laser light from the VCSEL. With this configuration, the laser light emitted from the resin 350 can be collected.

The shape of the emission surface of the module is not limited to convex, but it may be plane or concave. For example, in a module 302 shown in FIG. 10B, the upper surface of the resin 350 is formed into a plane 362. With this shape, the laser light having a divergence angle θ can be emitted outside with that angle. The module 300 or 320 may include a light receiving device or a thermal sensor within the resin 28 in order to monitor the emitting status of the VCSEL.

FIG. 11 illustrates an example of a configuration in which a VCSEL is used as a light source. A light source device 370 may include the module 300 or 302 shown in FIG. 10A or FIG. 10B, a collimator lens 372 that receives multi-beam laser light from the optical device 300 or 302, a polygon mirror 374 that rotates at a certain speed and reflects the light rays from the collimator lens 372 with a certain divergence angle, an fθ lens 376 that receives laser light from the polygon mirror 374 and projects the laser light onto a line-shaped reflective mirror 378, the reflective mirror 378, and a light sensitive drum 380 that forms a latent image based on the reflected light from the reflective mirror 378. As described above, a VCSEL can be used as a light source for an optical data processing device, for example, a copier or printer that includes an optical system that collects laser light from a VCSEL onto a light sensitive drum, and a mechanism that scans the collected laser light on the light sensitive drum.

FIG. 12 is a cross sectional view illustrating a configuration in which the module shown in FIG. 10A is applied to a light source. A light source 400 may include a cylindrical housing 410 adhered and fixed to the side surface of the module 300, a sleeve 420 formed integral with the housing 410 on an edge surface thereof, a ferrule 430 held in an opening 422 of the sleeve 420, and an optical fiber 440 held by the ferrule 430. The ferrule 430 is positioned exactly in the opening 422 of the sleeve 420, and the optical axis of the optical fiber 440 is aligned with the optical axis of the semiconductor light-emitting device 10. In a through hole 432 of the ferrule 430, the core of the optical fiber 440 is held.

Laser light emitted from the VCSEL 310 is concentrated by the convex portion 360 of the resin 350. The concentrated light is injected into the core of the optical fiber 440, and transmitted. The light source 400 may further include a receiving function for receiving an optical signal via the optical fiber 440.

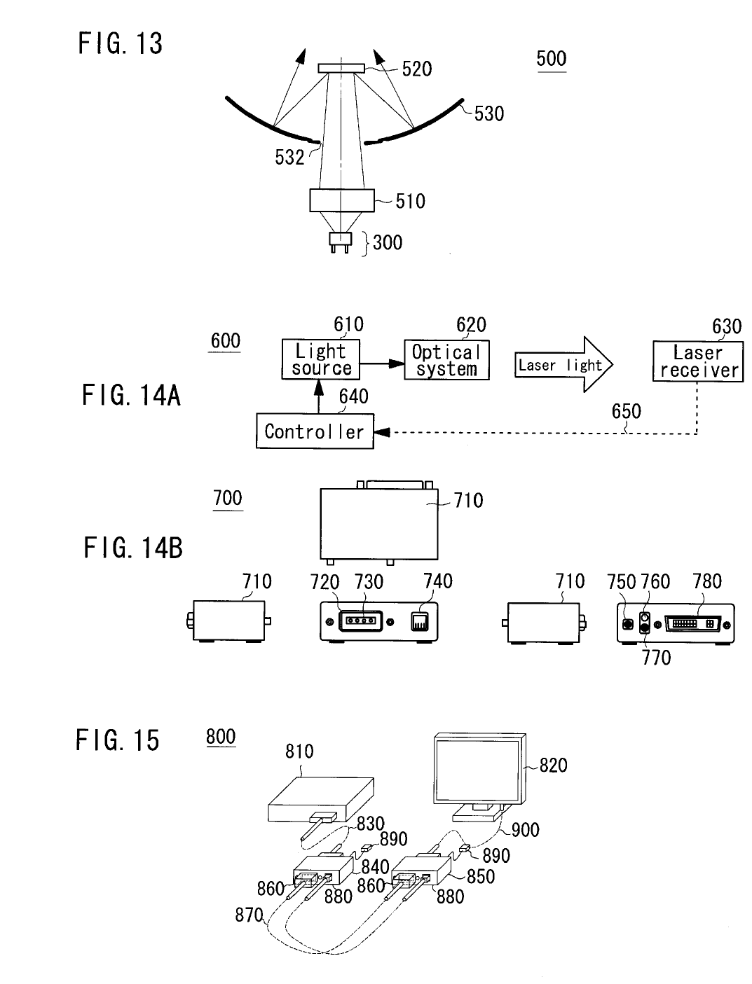

FIG. 13 illustrates a configuration in which the module shown in FIG. 12 is used in a spatial transmission system. A spatial transmission system 500 may include the module 300, a condensing lens 510, a diffusing plate 520, and a reflective mirror 530. The light concentrated by the condensing lens 510 passes through an opening 532 of the reflective mirror 530 and is reflected by the diffusing plate 520. The reflected light is reflected toward the reflective mirror 530. The reflective mirror 530 reflects the reflected light toward a predetermined direction to perform optical transmission.

FIG. 14A illustrates an example of a configuration of an optical transmission system in which a VCSEL is used as a light source. An optical transmission system 600 may include a light source 610 that contains the chip 310 in which a VCSEL is formed, an optical system 620, for example, for concentrating laser light that is emitted from the light source 610, a light receiver 630 for receiving laser light that is outputted from the optical system 620, and a controller 640 for controlling the driving of the light source 610. The controller 640 may provide a driving pulse signal for driving the VCSEL to the light source 610. The light emitted from the light source 610 is transmitted through the optical system 620 to the light receiver 630 by means of an optical fiber, or a reflective mirror for spatial transmission, or the like. The light receiver 630 may detect received light by a photo-detector, for example. The light receiver 630 is capable of controlling operations (for example, the start timing of optical transmission) of the controller 640, by a control signal 650.

FIG. 14B illustrates a configuration of an optical transmission device used for an optical transmission system. An optical transmission device 700 may include a case 710, an optical signal transmitting/receiving connector 720, a light emitting/light receiving element 730, an electrical signal cable connector 740, a power input 750, an LED 760 for indicating normal operation, an LED 770 for indicating an abnormality, and a DVI connector 780, and have a transmitting circuit board/receiving circuit board mounted inside.

FIG. 15 illustrates a video transmission system in which the optical transmission device 700 is used. A video transmission system 800 uses the optical transmission device shown in FIG. 14B for transmitting a video signal generated at a video signal generator 810 to an image display 820 such as a liquid crystal display. More specifically, the video transmission system 800 may include the video signal generator 810, the image display 820, an electrical cable 830 for DVI, a transmitting module 840, a receiving module 850, connectors 860 for a video signal transmission optical signal, an optical fiber 870, electrical cable connectors 880 for a control signal, power adapters 890, and an electrical cable 900 for DVI.

A VCSEL device according to an aspect of the present invention can be used in fields such as optical data processing or optical high-speed data communication.

The foregoing description of the examples has been provided for the purposes of illustration and description, and it is not intended to limit the scope of the invention. It should be understood that the invention may be implemented by other methods within the scope of the invention that satisfies requirements of a configuration of the present invention.

What is claimed is:

1. A Vertical-Cavity Surface-Emitting Laser diode (VCSEL) device comprising:
a substrate on which at least a first semiconductor multilayer film of a first conductivity type, an active region, and a second semiconductor multilayer film of a second conductivity type are stacked, the second semiconductor multilayer film forming a resonator together with the first semiconductor multilayer film;
a first protecting layer being conductive and formed in an area in the second semiconductor multilayer film, the area comprising at least an emission outlet that emits laser light;
an annular electrode formed on the first protecting layer, the emission outlet being formed in the annular electrode; and
an encapsulating material that encapsulates at least the first protecting layer and the annular electrode.

2. The VCSEL device according to claim 1, wherein the first protecting layer is a metal thin film that allows laser light to pass through.

3. The VCSEL device according to claim 1, wherein the VCSEL further comprising a second protecting layer that covers the emission outlet in the annular electrode.

4. The VCSEL device according to claim 1, wherein a post is formed on the substrate, and the annular electrode is formed at a top portion of the post, and at least the side surface of the post and a portion of the top portion of the post are covered with an interlayer insulating film, and an upper electrode is connected to the annular electrode that is not covered with the interlayer insulating film.

5. A Vertical-Cavity Surface-Emitting Laser diode (VCSEL) device comprising:
a substrate on which at least a first semiconductor multilayer film of a first conductivity type, an active region, and a second semiconductor multilayer film of a second conductivity type are stacked, the second semiconductor multilayer film forming a resonator together with the first semiconductor multilayer film;
an annular electrode formed on the second semiconductor multilayer film and having an emission outlet that emits laser light;
an emission protecting layer that covers the emission outlet in the annular electrode;
an interface protecting layer that covers at least the annular electrode and the emission protecting layer; and
an encapsulating material that covers at least the interface protecting layer.

6. The VCSEL device according to claim 5, wherein the interface protecting layer is a conductive film or an insulating film, the conductive film or an insulating film allowing laser light to pass through.

7. The VCSEL device according to claim 5, wherein a post is formed on the substrate, and the annular electrode is formed at a top portion of the post, and at least the side surface of the post and a portion of the top portion of the post are covered with an interlayer insulating film, and an upper electrode is connected to the annular electrode that is not covered with the interlayer insulating film.

8. The VCSEL device according to claim 1, wherein the encapsulating material is an optical transparent resin.

9. The VCSEL device according to claim 1, wherein each of the first and second semiconductor multilayer films is made of a III-V group semiconductor layer that comprises Al, and the second semiconductor multilayer film comprises a GaAs contact layer on the surface thereof.

10. The VCSEL device according to claim 4, wherein the post comprises a current confining layer that is formed by selectively oxidizing a portion of the semiconductor layer that comprises Al from a side surface of the post.

11. A module comprising;
a VCSEL device, and
an optical material,
the VCSEL device including a substrate on which at least a first semiconductor multilayer film of a first conductivity type, an active region, and a second semiconductor multilayer film of a second conductivity type are stacked, the second semiconductor multilayer film forming a resonator together with the first semiconductor multilayer film, a first protecting layer being conductive and formed in an area in the second semiconductor multilayer film, the area comprising at least an emission outlet that emits laser light, an annular electrode formed on the first protecting layer, the emission outlet being formed in the annular electrode, and an encapsulating material that encapsulates at least the first protecting layer and the annular electrode.

12. A light source comprising:
a module;
an optical unit; and
a sending unit that sends laser light that is emitted from the module through the optical unit,
the module including a VCSEL device, and an optical material,
the VCSEL device including a substrate on which at least a first semiconductor multilayer film of a first conductivity type, an active region, and a second semiconductor multilayer film of a second conductivity type are stacked, the second semiconductor multilayer film forming a resonator together with the first semiconductor multilayer film, a first protecting layer being conductive and formed in an area in the second semiconductor multilayer film, the area comprising at least an emission outlet that emits laser light, an annular electrode formed on the first protecting layer, the emission outlet being formed in the annular electrode, and an encapsulating material that encapsulates at least the first protecting layer and the annular electrode.

13. A free space optical communication device comprising:
a module according to claim 11; and
a transmission unit that spatially transmits light that is emitted from the module,
the module including a VCSEL device, and an optical material,
the VCSEL device including a substrate on which at least a first semiconductor multilayer film of a first conductivity type, an active region, and a second semiconductor multilayer film of a second conductivity type are stacked, the second semiconductor multilayer film forming a resonator together with the first semiconductor multilayer film, a first protecting layer being conductive and formed in an area in the second semiconductor multilayer film, the area comprising at least an emission outlet that emits laser light, an annular electrode formed on the first protecting layer, the emission outlet being formed in the annular electrode, and an encapsulating material that encapsulates at least the first protecting layer and the annular electrode.

14. A light sending system comprising:
a module; and
a sending unit that sends laser light that is emitted from the module,
the module including a VCSEL device, and an optical material,
the VCSEL device including a substrate on which at least a first semiconductor multilayer film of a first conductivity type, an active region, and a second semiconductor multilayer film of a second conductivity type are stacked, the second semiconductor multilayer film forming a resonator together with the first semiconductor multilayer film, a first protecting layer being conductive and formed in an area in the second semiconductor multilayer film, the area comprising at least an emission outlet that emits laser light, an annular electrode formed on the first protecting layer, the emission outlet being formed in the annular electrode, and an encapsulating material that encapsulates at least the first protecting layer and the annular electrode.

15. A free space optical communication system comprising:
a module;
a transmission unit that spatially transmits light that is emitted from the module,
the module including a VCSEL device, and an optical material,
the VCSEL device including a substrate on which at least a first semiconductor multilayer film of a first conductivity type, an active region, and a second semiconductor multilayer film of a second conductivity type are stacked, the second semiconductor multilayer film forming a resonator together with the first semiconductor multilayer film, a first protecting layer being conductive and formed in an area in the second semiconductor multilayer film, the area comprising at least an emission outlet that emits laser light, an annular electrode formed on the first protecting layer, the emission outlet being formed in the annular electrode, and an encapsulating material that encapsulates at least the first protecting layer and the annular electrode.

16. A method for fabricating a Vertical-Cavity Surface-Emitting Laser diode (VCSEL) device, comprising:
stacking semiconductor layers that include at least a first semiconductor multilayer film of a first conductivity type, an active region, and a second semiconductor multilayer film of a second conductivity type on a substrate, the second semiconductor multilayer film forming a resonator together with the first semiconductor multilayer film;
forming a first protecting layer in an area in the second semiconductor multilayer film, the first protecting layer being conductive, and the area comprising at least an emission outlet that emits laser light;
forming an annular electrode on the first protecting layer, the emission outlet being formed in the annular electrode;
forming a groove in the semiconductor layers to form a post on the substrate, the post comprising the annular electrode at a top portion thereof; and
resin encapsulating at least the substrate.

17. The method for fabricating a VCSEL device according to claim 16, further comprising; forming a second protecting layer that covers the emission outlet in the annular electrode.
